(19) United States
(12) Patent Application Publication
(10) Pub. No.: US 2025/0096523 A1
(43) Pub. Date: Mar. 20, 2025

(54) LIGHT-EMITTING DEVICE AND MANUFACTURING METHOD OF LIGHT-EMITTING DEVICE

(71) Applicant: NICHIA CORPORATION, Anan-shi (JP)

(72) Inventor: Tadayuki KITAJIMA, Itano-gun (JP)

(21) Appl. No.: 18/884,086

(22) Filed: Sep. 12, 2024

(30) Foreign Application Priority Data
Sep. 15, 2023 (JP) 2023-149905

(51) Int. Cl. H01S 5/02345; H01S 5/0225; H01S 5/02315

(52) U.S. Cl. CPC H01S 5/02345; H01S 5/0225; H01S 5/02315

(57) ABSTRACT

A light-emitting device includes a base, a first metal member, a second metal member, a semiconductor laser element, and a lid body. The base has an upper surface and a lower surface. The first metal member is disposed on the upper surface of the base and has a thickness in a vertical direction in a range from 50 μm to 150 μm. The second metal member is disposed on the upper surface of the base and has a thickness in the vertical direction identical to the thickness of the first metal member. The second metal member is spaced apart from the first metal member in a top view and surrounds the first metal member. The semiconductor laser element is disposed on the first metal member. The lid body is bonded to the base via the second metal member.

### CROSS-REFERENCE TO RELATED APPLICATIONS

This application claims priority to Japanese Patent Application No. 2023-149905, filed on Sep. 15, 2023, the disclosure of which is hereby incorporated herein by reference in its entirety.

### BACKGROUND

The present invention relates to a light-emitting device and a manufacturing method of a light-emitting device.

Japanese Laid-Open Patent Publication No. 2021-163950 A discloses an optical semiconductor package including a package substrate provided with a surface electrode and a metal layer, an optical semiconductor chip bonded to the surface electrode, and a translucent lid bonded to the metal layer.

### SUMMARY

One aspect of the present disclosure is directed to a light-emitting device that achieves reduced variation in accuracy due to tolerance occurring in manufacturing the light-emitting device.

Another aspect of the present disclosure is directed to a light-emitting device that achieves balanced stress applied to a base of a package.

Another aspect of the present disclosure is directed to a small light-emitting device.

The present disclosure may also be directed to a light-emitting device that can achieve a plurality of aspects of the above-described aspects.

A light-emitting device disclosed in an embodiment includes a base, a first metal member, a second metal member, a semiconductor laser element, and a lid body. The base has an upper surface and a lower surface. The first metal member is disposed on the upper surface of the base and has a thickness in a vertical direction in a range from 50 μm to 150 μ. The second metal member is disposed on the upper surface of the base and has a thickness in the vertical direction identical to the thickness of the first metal member. The second metal member is spaced apart from the first metal member in a top view and surrounds the first metal member. The semiconductor laser element is disposed on the first metal member. The lid body is bonded to the base via the second metal member.

A manufacturing method of a light-emitting device disclosed in an embodiment includes: preparing a base having an upper surface and a lower surface; providing a first metal member and a second metal member on the upper surface of the base by the same treatment; disposing a semiconductor laser element on the first metal member; and bonding the base and a lid body via the second metal member. The first metal member and the second metal member have a thickness in a vertical direction identical to each other, and the thickness is in a range from 50 μto 150μ. In a top view, the first metal member is spaced apart from the second metal member and the second metal member surrounds the first metal member.

In at least one of one or more embodiments disclosed herein, a light-emitting device with reduced variation in accuracy due to tolerance can be achieved.

### BRIEF DESCRIPTION OF DRAWINGS

FIG. 1 is a schematic perspective view of a light-emitting device according to a first embodiment.

FIG. 2 is a top view of the light-emitting device according to the first embodiment.

FIG. 3 is a side view of the light-emitting device according to each embodiment.

FIG. 4 is a cross-sectional view of the light-emitting device according to each embodiment taken along cross section line IV-IV in FIGS. 2 and 11.

FIG. 5A is a cross-sectional view of the light-emitting device according to the first embodiment taken along cross section line VA-VA in FIG. 2.

FIG. 5B is a partially enlarged view of FIG. 5A for explaining detailed structures of an upper metal member, a wiring portion, and a bonding pattern.

FIG. 6 is a perspective view illustrating components disposed inside a package of the light-emitting device according to the first embodiment.

FIG. 7 is a top view illustrating the components disposed inside the package of the light-emitting device according to the first embodiment.

FIG. 8 is a bottom view of the package according to the first embodiment.

FIG. 9 is a cross-sectional view of a package according to each embodiment taken along cross section line IX-IX in FIGS. 8 and 15.

FIG. 10 is a schematic perspective view of a light-emitting device according to a second embodiment.

FIG. 11 is a top view of the light-emitting device according to the second embodiment.

FIG. 12A is a cross-sectional view of the light-emitting device according to the second embodiment taken along cross section line XIIA-XIIA of FIG. 11.

FIG. 12B is a partially enlarged view of FIG. 12A for explaining detailed structures of an upper metal member, a wiring portion, and a bonding pattern.

FIG. 13 is a perspective view illustrating components disposed inside a package of the light-emitting device according to the second embodiment.

FIG. 14 is a top view illustrating the components disposed inside the package of the light-emitting device according to the second embodiment.

FIG. 15 is a bottom view of the package according to the second embodiment.

### DETAILED DESCRIPTION

In the present description or the claims, polygons such as triangles and quadrangles, including shapes in which the corners of the polygon are rounded, beveled, chamfered, or coved, are referred to as polygons. A shape obtained by processing not only the corners (ends of a side) but also an intermediate portion of the side is similarly referred to as a polygon. That is, a shape that is partially processed while remaining a polygon shape as a base is included in the interpretation of “polygon” described in the present description and the claims.

The same applies not only to polygons but also to words representing specific shapes such as trapezoids, circles, protrusions, and recesses. The same applies when dealing with each side forming that shape. That is, even if processing is performed on a corner or an intermediate portion of a certain side, the interpretation of “side” includes the processed portion. When a “polygon” or “side” not partially processed is to be distinguished from a processed shape, “exact” will be added to the description as in, for example, “exact quadrangle”.

In the present description or the claims, descriptions such as upper and lower (upward/downward), left and right, surface and reverse, front and back (forward/backward), and near and far are used merely to describe the relative relationship of positions, orientations, and directions, and the expressions do not necessarily match an actual relationship at the time of use.

In the drawings, directions such as an X direction, a Y direction, and a Z direction may be indicated by using arrows. The directions of the arrows are consistent across multiple drawings of the same embodiment. In the drawings, the directions of the arrows marked with X, Y, and Z are the positive directions, and the opposite directions are the negative directions. For example, the direction marked with X at the tip of the arrow is the X direction and the positive direction. In the present description, the direction that is the X direction and is the positive direction will be referred to as the “positive direction of X” and the direction opposite to this will be referred to as the “negative direction of X”. The term “X direction” includes both the positive direction and the negative direction. The same applies to the Y direction and the Z direction.

In the present description, when a certain object is specified as “one or more” and the object is described, an embodiment in which the object is one and an embodiment in which the object is plural are collectively described. Thus, a description specified as “one or more” supports every case of an embodiment including one or more objects, an embodiment including at least one object, and an embodiment including a plurality of objects.

In the present description, the description illustrating “one or each” object is a description summarizing a description of one object in an embodiment including the one object, a description of one object in an embodiment including a plurality of objects, and a description of each of a plurality of objects in an embodiment including the plurality of objects. Thus, the description illustrating “one or each” object supports every case of an embodiment including one object in which the one object satisfies the described content, an embodiment including a plurality of objects in which, among these objects, at least one of the objects satisfies the described content, and an embodiment including a plurality of objects in which each of these plurality of objects satisfies the described content, and an embodiment including one or more objects in which all of the objects satisfy the described content.

The term “member” or “portion” may be used to describe, for example, a component in the present description. The term “member” refers to an object physically treated alone. The object physically treated alone can be an object treated as one part in a manufacturing process. Meanwhile, the term “portion” refers to an object that need not be physically treated alone. For example, the term “portion” is used when part of one member is partially considered, or a plurality of members are collectively considered as one object.

The distinction between “member” and “portion” described above does not indicate an intention to consciously limit the scope of right in interpretation of the doctrine of equivalents. That is, even when a component described as “member” is present in the claims, this does not mean that the applicant recognizes that physically treating the component alone is essential in the application of the present invention.

In the present description or the claims, when a plurality of components are present and these components are to be indicated separately, the components may be distinguished by adding “first” and “second” at the beginning of the names of the components. Objects to be distinguished may differ between the present description and the claims. Thus, even when a component in the claims is given the same term as that in the present description, the object identified by that component is not the same across the present description and the claims in some cases.

For example, when components distinguished by being given “first”, “second”, and “third” are present in the present description, and when components given “first” and “third” in the present description are described in the claims, these respective components may be distinguished by being given “first” and “second” in the claims for ease of understanding. In this case, the components given “first” and “second” in the claims refer to the components given “first” and “third” in the present description, respectively. This rule applies to not only components but also other objects in a reasonable and flexible manner.

Embodiments for implementing the present invention will be described below. Specific embodiments for implementing the present invention will be described below with reference to the drawings. Embodiments for implementing the present invention are not limited to the specific embodiments. That is, the embodiments illustrated by the drawings are not the only embodiment in which the present invention is achieved. Sizes and positional relationships of members illustrated in each of the drawings may sometimes be exaggerated in order to facilitate understanding.

### First Embodiment

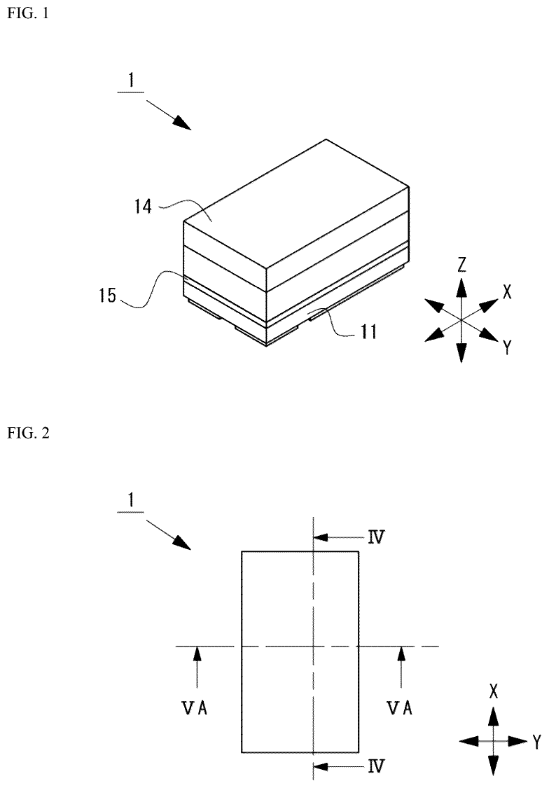

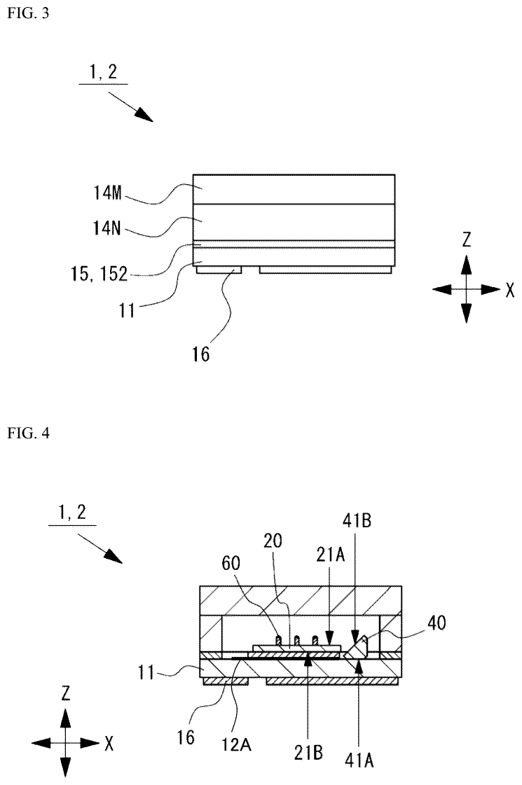

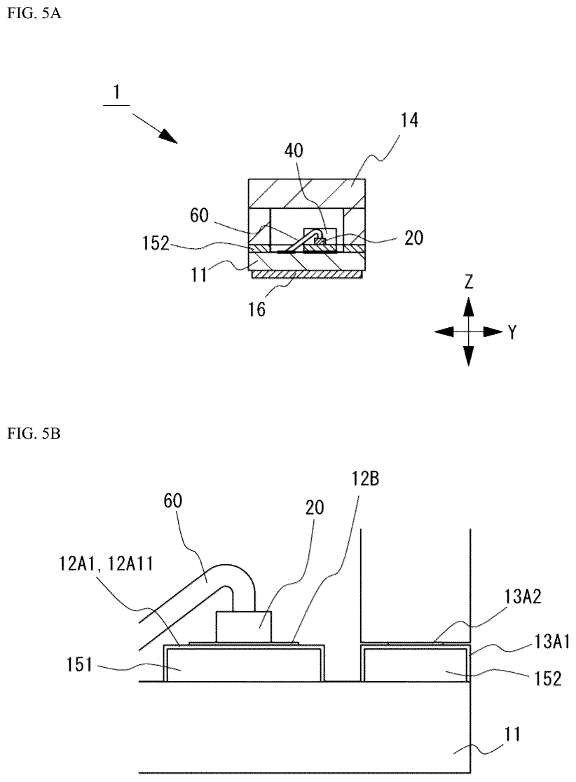

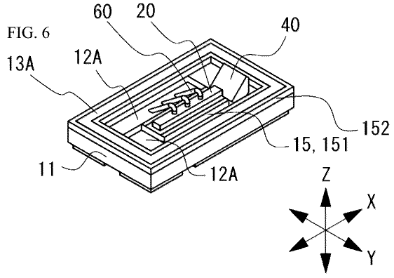

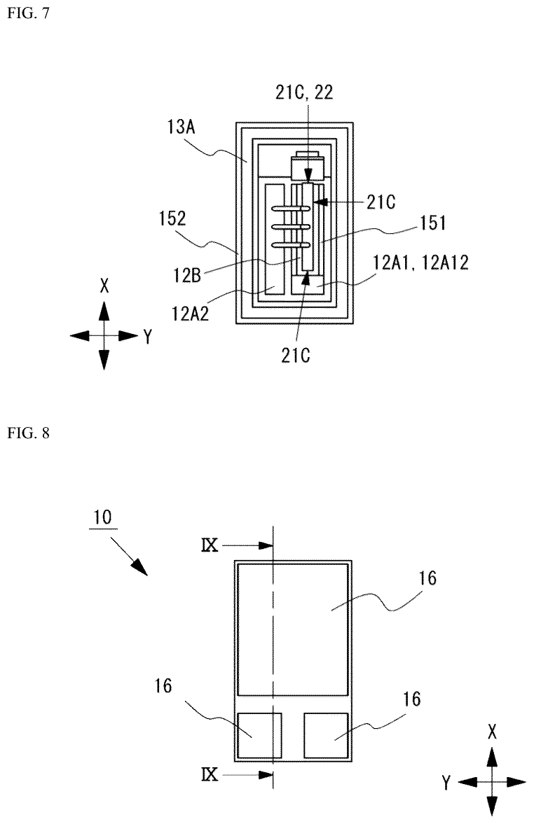

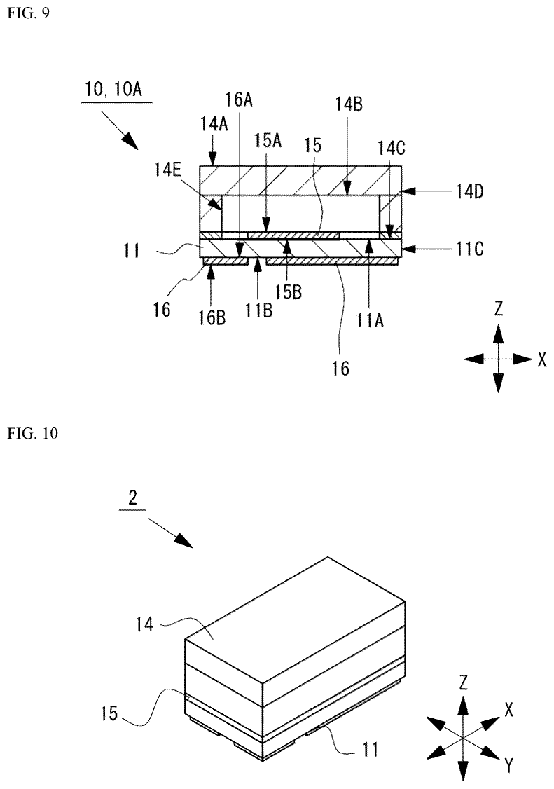

A light-emitting device 1 according to a first embodiment will now be described. FIGS. 1 to 9 are drawings for illustrating an exemplary embodiment of the light-emitting device 1. FIG. 1 is a perspective view of the light-emitting device 1. FIG. 2 is a top view of the light-emitting device 1. FIG. 3 is a side view of the light-emitting device 1. FIG. 4 is a cross-sectional view of the light-emitting device 1 taken along cross section line IV-IV in FIG. 2. FIG. 5A is a cross-sectional view of the light-emitting device 1 taken along cross section line V-V in FIG. 2. FIG. 5B is a partially enlarged view of FIG. 5A for explaining detailed structures of an upper metal member 15, a wiring portion 12A, and a bonding pattern 13A. FIG. 6 is a perspective view illustrating components disposed inside a package 10 of the light-emitting device 1. FIG. 7 is a top view illustrating the components disposed inside the package 10 of the light-emitting device 1. FIG. 8 is a bottom view of the package 10. FIG. 9 is a cross-sectional view of the package 10 taken along cross section line IX-IX of FIG. 8.

The light-emitting device 1 includes a plurality of components. The plurality of components includes a package 10, one or more semiconductor laser elements 20, one or more reflective members 40, and one or more wiring lines 60.

The light-emitting device 1 may include a component other than the components described above. For example, the light-emitting device 1 may further include a semiconductor laser element separately from the one or more semiconductor laser elements 20. The light-emitting device 1 need not include some of the components described above.

Firstly, each of the components will be described.

### Package 10

The package 10 includes the base 11 and a lid body 14. The package 10 includes one or more upper metal members 15. The package 10 includes one or more lower metal members 16. The lid body 14 is bonded to the base 11 to form the package 10. An internal space in which other components are disposed is defined in the package 10. The internal space is a closed space surrounded by the base 11 and the lid body 14. The internal space can also be a sealed space in a vacuum or airtight state.

The outer edge shape of the package 10 in a top view is rectangular. This rectangular shape can be a rectangular shape with long sides and short sides. In the illustrated package 10, the long-side direction of the rectangular shape is the same direction as the X direction, and the short-side direction of the rectangular shape is the same direction as the Y direction. The outer edge shape of the package 10 in a top view need not be rectangular.

The internal space in which other components are disposed is formed in the package 10. An upper surface 11A of the package 10 is a part of a region defining the internal space. Each inner lateral surface 14E and a first lower surface 14B of the package 10 are parts of the region defining the internal space.

The base 11 has the upper surface 11A and a lower surface 11B. The base 11 has one or more lateral surfaces 11C. The base 11 is configured in a cuboid flat plate shape. The shape of the base 11 needs not be a cuboid.

One or each of the upper metal members 15 has an upper surface 15A and a lower surface 15B. One or each of the upper metal members 15 is provided on the upper surface 11A of the base 11. The one or more upper metal members 15 include a first metal member 151 and a second metal member 152.

One or each of the upper metal members 15 has a thickness in a vertical direction in a range from 50 μm to 150 μm. The first metal member 151 and the second metal member 152 have the same thickness in the vertical direction. Here, “same” includes a difference of ±5 μm or less.

The first metal member 151 and the second metal member 152 are spaced apart from each other in a top view. The second metal member 152 surrounds the first metal member 151 in a top view. The second metal member 152 is provided in the vicinity of an outer edge of the upper surface 11A of the base 11 in a top view.

The shape of the second metal member 152 in a top view is a rectangular annular shape. The shape of the second metal member 152 in a top view is a shape surrounded by two rectangular shapes having different sizes. These two rectangular shapes have centers overlapping each other, and a difference in width in the long-side direction is equal to a difference in width in the short-side direction. The minimum width of the second metal member 152 in a top view is in a range from 200 μm to 400 μm.

The base 11 has one or more wiring portions 12A. The one or more wiring portions 12A include a first wiring portion 12A1 and a second wiring portion 12A2. The first wiring portion 12A1 and the second wiring portion 12A2 are spaced apart from each other in a top view.

The first wiring portion 12A1 is provided on the upper surface 11A of the package 10. The second wiring portion 12A2 is provided on the upper surface 11A of the package 10. Each of the first wiring portion 12A1 and the second wiring portion 12A2 is electrically connected to a conductive member disposed in a through hole provided in the base 11.

One or each of the wiring portions 12A has a thickness in the vertical direction in a range from 0.2 μm to 5 μm. The thickness in the vertical direction of one or each of the wiring portions 12A is smaller than the thickness in the vertical direction of the upper metal member 15. The thickness in the vertical direction of one or each of the wiring portions 12A is sufficiently smaller than the thickness in the vertical direction of the upper metal member 15, and is 0.1 times or less the thickness in the vertical direction of the upper metal member 15. Since it is sufficient that electrical connection with the conductive member is achieved, the wiring portion 12A can be formed without requiring a thickness as large as that of the upper metal member 15.

The first wiring portion 12A1 is spaced apart from the second metal member 152 in a top view. The first metal member 151 is provided on the first wiring portion 12A1. The first wiring portion 12A1 has a portion (hereinafter, referred to as a first region 12A11 of the first wiring portion 12A1) overlapping the first metal member 151 and a portion (hereinafter, referred to as a second region 12A12 of the first wiring portion 12A1) not overlapping the first metal member 151 in a top view. In the second portion 12A12 of the first wiring portion 12A1, the first wiring portion 12A1 is connected to the conductive member disposed in the through hole of the base 11. That is, in this portion, the first wiring portion 12A1 and the conductive member overlap with each other in a top view. A bonding layer 12B is provided on the first region 12A11 of the first wiring portion 12A1.

The second wiring portion 12A2 is spaced apart from the first metal member 151 in a top view. The second wiring portion 12A2 is spaced apart from the second metal member 152 in a top view. The second wiring portion 12A2 is positioned inside the second metal member 152 in a top view. The second wiring portion 12A2 is connected to the conductive member disposed in a through hole of the base 11. This through hole is a through hole different from the through hole provided with the conductive member connected to the first wiring portion 12A1.

The base 11 includes a bonding pattern 13A. The bonding pattern 13A is provided above the upper surface 11A. The bonding pattern 13A is provided annularly. The bonding pattern 13A is provided in a rectangular annular shape. In a top view, the bonding pattern 13A is provided in the vicinity of the outer edge of the upper surface 11A.

The bonding pattern 13A includes a first bonding pattern 13A1 and a second bonding pattern 13A2. The second bonding pattern 13A2 is provided on the first bonding pattern 13A1. The shape of the first bonding pattern 13A1 in a top view is the same as that of the second metal member 152 or includes the second metal member 152. The first bonding pattern 13A1 is provided on the second metal member 152. The second bonding pattern 13A2 is included in the first bonding pattern 13A1 in a top view. The shape of the second bonding pattern 13A2 is smaller than that of the second metal member 152. The thickness in the vertical direction of the first bonding pattern 13A1 is less than twice the thickness in the vertical direction of the first wiring portion 12A1. This can make the difference between the height smaller in the case of providing the first bonding pattern 13A1 than in the case of not providing the first bonding pattern 13A1.

The thickness in the vertical direction of the first bonding pattern 13A1 is the same as the thickness in the vertical direction of the first wiring portion 12A1. Here, “same” includes a difference within ±2 μm.

One or each of the lower metal members 16 has an upper surface 16A and a lower surface 16B. One or each of the lower metal members 16 is provided on the lower surface 11B of the base 11. One or each of the lower metal members 16 has a thickness in a vertical direction in a range from 50 μm to 150 μm.

A difference between the thickness in the vertical direction of the lower metal member 16 and the thickness in the vertical direction of the upper metal member 15 is in a range from 0 μm to 50 μm. Not increasing the difference between the thicknesses of the upper metal member 15 and the lower metal member 16 allows the stress applied to the base 11 to be balanced. For example, the thickness in the vertical direction of the lower metal member 16 is the same as the thickness in the vertical direction of the upper metal member 15. Here, “same” includes a difference of ±5 μm or less.

The one or more lower metal members 16 include a lower metal member 16 overlapping a part or the entirety of the first metal member 151 in a top view. The one or more lower metal members 16 include a lower metal member 16 overlapping at least a part of the second metal member 152 in a top view. When the one or more lower metal members 16 are viewed as a whole, it is deemed that the one or more lower metal members 16 have a portion overlapping the first metal member 151 and a portion overlapping the second metal member 152 in a top view.

The lower metal member 16 overlapping the first metal member 151 and the lower metal member 16 overlapping the second metal member 152 in a top view may be the same lower metal member 16 or different lower metal members 16. The one or more lower metal members 16 can include a lower metal member 16 overlapping a part or the entirety of the first metal member 151 and at least a part of the second metal member 152 in a top view.

The one or more lower metal members 16 include a lower metal member 16 electrically connected to the first wiring portion 12A1 via a conductive member provided in the through hole of the base 11. This lower metal member 16 is electrically connected to the first metal member 151.

The one or more lower metal members 16 include a lower metal member 16 electrically connected to the second wiring portion 12A2 via the conductive member provided in the through hole of the base 11. The one or more lower metal members 16 include a lower metal member 16 electrically connected to the first wiring portion 12A1 and a lower metal member 16 electrically connected to the second wiring portion 12A2.

In a top view, of the second metal member 152, the area of the region overlapping the one or more lower metal members 16 is larger than the area of the region not overlapping the one or more lower metal members 16. Providing the one or more lower metal members 16 in this manner allows the stress to be balanced with the second metal member 152.

The one or more lower metal members 16 do not include a lower metal member 16 electrically connected to the second metal member 152. The one or more lower metal members 16 do not include a lower metal member 16 having a rectangular annular shape in a bottom view.

The base 11 can be formed using a ceramic as a main material, for example. Examples of the ceramic as the main material of the base 11 include aluminum nitride, silicon nitride, aluminum oxide, and silicon carbide.

The main material as used herein refers to a material that accounts for the greatest proportion of a target formed product in terms of mass or volume. When a target formed product is formed of a single material, the material is the main material. In other words, when a certain material is the main material, the proportion of the material may be 100%.

The wiring portion 12A and the first bonding pattern 13A1 can be formed using a metal material as a main material, for example. Examples of the metal material as the main material of the wiring portion 12A and the first bonding pattern 13A1 include single-component metals, such as Cu, Ag, Ni, Au, Ti, Pt, Pd, Cr, and W, and alloys containing any of these metals. The wiring portion 12A and the first bonding pattern 13A1 can be constituted by one or more metal layers, for example.

The bonding layer 12B and the second bonding pattern 13A2 can be formed using a metal material as a main material, for example. Examples of the metal material as the main material of the bonding layer 12B and the second bonding pattern 13A2 include single-component metals, such as Cu, Ag, Ni, Au, Sn, Ti, and Pd, and alloys containing any of these metals. The bonding layer 12B and the second bonding pattern 13A2 can be constituted by one or more metal layers, for example.

The lid body 14 has an upper surface 14A and a first lower surface 14B. The lid body 14 has a second lower surface 14C. The lid body 14 has one or more outer lateral surfaces 14D. The lid body 14 has one or more inner lateral surfaces 14E. The one or more outer lateral surfaces 14D intersect the upper surface 14A. The one or more outer lateral surfaces 14D intersect the second lower surface 14C. The one or more inner lateral surfaces 14E intersect the first lower surface 14B. The one or more inner lateral surfaces 14E intersect the second lower surface 14C.

The outer edge shape of the lid body 14 in a top view is rectangular. The outer edge shape of the lid body 14 in a top view is the outer edge shape of the package 10. The outer edge shape of the upper surface 14A in a top view is rectangular. This rectangular shape can be a rectangular shape with long sides and short sides. The long-side direction of the upper surface 14A and the long-side direction of the outer edge shape of the lid body 14 are parallel. The outer edge shape of the upper surface 14A in a top view needs not be rectangular.

In a bottom view, the first lower surface 14B is surrounded by the second lower surface 14C. The second lower surface 14C is an annular surface surrounding the first lower surface 14B in a bottom view. The second lower surface 14C is a surface having a rectangular annular shape. Here, a frame defined by an inner edge of the second lower surface 14C is referred to as an inner frame of the second lower surface 14C, and a frame defined by an outer edge of the second lower surface 14C is referred to as an outer frame of the second lower surface 14C.

The lid body 14 has a recess portion surrounded by a frame by the second lower surface 14C. The recess portion defines a portion recessed upward relative to the second lower surface 14C in the lid body 14. The first lower surface 14B is a part of the recess portion. The one or more inner lateral surfaces 14E are a part of the recess portion. The first lower surface 14B is positioned upward relative to the second lower surface 14C.

The lid body 14 has a lid portion 14M and a frame portion 14N. The lid portion 14M and the frame portion 14N may be members made of materials different from each other. The lid body 14 can be configured to include a lid member corresponding to the lid portion 14M and a frame member corresponding to the frame portion 14N.

The lid portion 14M includes the upper surface 14A. The lid portion 14M includes the first lower surface 14B. The frame portion 14N includes the second lower surface 14C. The frame portion 14N includes the one or more outer lateral surfaces 14D and the one or more inner lateral surfaces 14E.

The lid body 14 is bonded to the base 11. The lid body 14 is bonded to the base 11 via the second metal member 152. The second lower surface 14C of the lid body 14 is bonded to the upper surface 11A of the base 11. The lid body 14 is bonded to the base 11 via the bonding pattern 13A and the second metal member 152. The lid body 14 is bonded to the second metal member 152 via an adhesive.

By bonding the lid body 14 to the base 11 via the second metal member 152, it is possible to accurately uniform the height of a bonding surface (the upper surface 15A of the second metal member 152) of the base 11 bonded to the lid body 14 and the height of the upper surface 15A of the first metal member 151. This makes the distance from the upper surface 15A of the first metal member 151 to the upper surface 14A of the package 10 less likely to be affected by member tolerance of the upper metal member 15 and reduces variation in accuracy.

The lid body 14 has light transmissivity to transmit light. The description “light transmissivity” as used herein refers to that the transmittance of light incident on the lid body 14 is 80% or more. The lid body 14 may partially include a non-light transmitting region (a region with no light transmissivity).

The lid body 14 can be formed using glass as a main material, for example. The lid body 14 may be formed using a lid member and a frame member formed using different main materials. The lid member can be formed using a light transmissive material such as glass or sapphire as a main material, for example. The frame member can be formed using glass or ceramic as a main material, for example. Examples of the ceramic as the main material of the frame member include aluminum nitride, silicon nitride, aluminum oxide, and silicon carbide.

The width in the X direction of the package 10 can be in a range from 2 mm to 4 mm. The width in the Y direction of the package 10 can be in a range from 1.3 mm to 3 mm. The width in the Z direction of the package 10 can be in a range from 1 mm to 3 mm. The width in the Z direction of the base 11 can be in a range from 0.2 mm to 1 mm. The width in the Z direction of the lid body 14 can be in a range from 0.6 mm to 2 mm. In the illustrated light-emitting device 1, the width in the Z direction is the same as the width in the vertical direction.

The thickness in the vertical direction of the upper metal member 15 can be in a range from 0.15 times to 0.5 times the thickness in the vertical direction of the base 11. Preferably, the thickness in the vertical direction of the upper metal member 15 is in a range from 0.2 times to 0.5 times the thickness in the vertical direction of the base 11 and is in a range from 50 μm to 100 μm. Setting the thickness of the upper metal member 15 to 50 μm or more can have the height from the upper surface 11A to the upper surface 15A. Setting the ratio of these thicknesses to 0.5 times or less can suppress the height of the package 10.

### Semiconductor Laser Element 20

The semiconductor laser element 20 has an upper surface 21A, a lower surface 21B, and a plurality of lateral surfaces 21C. The shape of the upper surface 21A is a rectangular shape having a long side and a short side. An outer shape of the semiconductor laser element 20 in a top view is a rectangular shape having a long side and a short side. The shape of the upper surface 21A and the outer shape of the semiconductor laser element 20 in a top view are not limited to this.

The semiconductor laser element 20 has a light-emitting surface 22 that emits light. For example, the lateral surface 21C can be the light-emitting surface 22. The lateral surface 21C serving as the light-emitting surface 22 meets a short side of the upper surface 21A. For example, the upper surface 21A can be the light-emitting surface 22.

As the semiconductor laser element 20, a single-emitter semiconductor laser element including one emitter can be adopted. As the semiconductor laser element 20, a multi-emitter semiconductor laser element including a plurality of emitters can be adopted.

As the semiconductor laser element 20, a semiconductor laser element that emits blue light, for example, can be adopted. For example, as the semiconductor laser element 20, a semiconductor laser element that emits green light can be adopted. For example, as the semiconductor laser element 20, a semiconductor laser element that emits red light can be adopted. As the semiconductor laser element 20, a semiconductor laser element that emits light of another color or wavelength may be adopted.

Here, blue light refers to light having a light emission peak wavelength within a range from 420 nm to 494 nm. Green light refers to light having a light emission peak wavelength within a range from 495 nm to 570 nm. Red light refers to light having a light emission peak wavelength within a range from 605 nm to 750 nm.

Examples of the semiconductor laser element 20 that emits blue light or the semiconductor laser element 20 that emits green light include a semiconductor laser element including a nitride semiconductor. A GaN-based semiconductor, such as GaN, InGaN, or AlGaN, can be employed as the nitride semiconductor. Examples of the semiconductor laser element 20 that emits red light include a semiconductor laser element including a semiconductor of InAlGaP-based, GaInP-based, or GaAs-based such as GaAs and AlGaAs.

The semiconductor laser element 20 emits a directional laser beam. Divergent light having divergence is emitted from the light-emitting surface 22 (emitting end surface) of the semiconductor laser element 20. Light emitted from the semiconductor laser element 20 forms a far field pattern (“FFP”) having an elliptical shape in a surface parallel to the light-emitting surface 22. The FFP indicates a shape or a light intensity distribution of the emitted light at a position spaced apart from the light-emitting surface of the semiconductor laser element.

Here, light passing through the center of the elliptical shape of the FFP, in other words, light having a peak intensity in the light intensity distribution of the FFP is referred to as light traveling along an optical axis or light passing through an optical axis. In the light intensity distribution of the FFP, light having an intensity of 1/e² or more with respect to the peak intensity is referred to as a main portion of light.

The shape of the FFP of the light emitted from the semiconductor laser element 20 is an elliptical shape longer in the layering direction than in the direction perpendicular to the layering direction in the surface parallel to the light-emitting surface 22. The layering direction is a direction in which a plurality of semiconductor layers including an active layer are layered in the semiconductor laser element 20. The direction perpendicular to the layering direction can also be referred to as a plane direction of the semiconductor layer. A long diameter direction of the elliptical shape of the FFP can also be referred to as a fast axis direction of the semiconductor laser element 20, and a short diameter direction of the elliptical shape of the FFP can also be referred to as a slow axis direction of the semiconductor laser element 20.

Based on the light intensity distribution of the FFP, an angle at which light having a light intensity of 1/e² of a peak light intensity spreads is referred to as a divergence angle of light of the semiconductor laser element 20. Here, the divergence angle of light is indicated as an angle formed by light having the peak light intensity (light passing through an optical axis) and light having a light intensity of 1/e² of the peak light intensity. In some cases, the divergence angle of light can also be determined based on, for example, the light intensity that is half of the peak light intensity, other than being determined based on the light intensity of 1/e² of the peak light intensity. In the description herein, the term “divergence angle of light” by itself refers to a divergence angle of light at the light intensity of 1/e² of the peak light intensity.

The divergence angle in the fast axis direction of the light emitted from the semiconductor laser element 20 can be 15 degrees or more and less than 90 degrees. The divergence angle of the light in the slow axis direction can be more than 0 degrees and 8 degrees or less. Also, the divergence angle of the light in the fast axis direction is greater than the divergence angle of the light in the slow axis direction.

### Reflective Member 40

The reflective member 40 has a lower surface 41A, and a light-reflective surface 41B that reflects light. The light-reflective surface 41B is inclined with respect to the lower surface 41A. A straight line connecting a lower end and an upper end of the light-reflective surface 41B is inclined with respect to the lower surface 41A. An angle at which the light-reflective surface 41B is inclined with respect to the lower surface 41A is referred to as an inclination angle of the light-reflective surface 41B.

The light-reflective surface 41B is a flat surface. The light-reflective surface 41B may be a curved surface. The inclination angle of the light-reflective surface 41B is 45 degrees. The light-reflective surface 41B need not have an inclination angle of 45 degrees.

As the main material of the reflective member 40, glass or metal can be used. A heat-resistant material is preferably used as the main material of the reflective member 40. As the main material, for example, a glass such as quartz glass or borosilicate glass (BK7), or a metal such as Al can be used. The reflective member 40 can also be formed using Si as the main material.

When the main material is a reflective material such as Al, the light-reflective surface 41B can be formed of the main material. Instead of forming the light-reflective surface 41B with the main material, a general form of the reflective member 40 may be formed with the main material, and the light-reflective surface 41B may be formed on a surface of the general form. In this case, the light-reflective surface 41B can be formed using, for example, a layer of a metal such as Ag or Al, or a dielectric multilayer film of Ta₂O₅/SiO₂, TiO₂/SiO₂, or Nb₂O₅/SiO₂.

In the light-reflective surface 41B, the reflectance with respect to the peak wavelength of the light irradiated on the light-reflective surface 41B is 90% or more. The reflectance may be 95% or more. The reflectance may be 99% or more. The light reflectance is equal to or less than 100% or is less than 100%.

### Wiring Line 60

The wiring line 60 is a linear conductive material having bonding portions at both ends. The bonding portions at both ends serve as portions for bonding with other components. The wiring line 60 is used for electrical connection between two components. The wiring line 60 is, for example, a metal wire. The metal used can be, for example, gold, aluminum, silver, or copper.

Subsequently, the light-emitting device 1 will be described.

### Light-Emitting Device 1

In the light-emitting device 1, one or each of the semiconductor laser elements 20 is disposed in the internal space of the package 10. One or each of the semiconductor laser elements 20 is disposed on the upper surface 11A of the base 11. One or each of the semiconductor laser elements 20 is disposed on the first metal member 151. The semiconductor laser element 20 is bonded to the first metal member 151 via an adhesive.

Disposing the semiconductor laser element 20 on the first metal member 151 makes the distance from the semiconductor laser element 20 to the upper surface 14A of the package 10 less likely to be affected by member tolerance of the upper metal member 15 and reduces variation in accuracy.

Disposing the first metal member 151 in the first portion of the first wiring portion 12A1 and not in the second portion of the first wiring portion 12A1 allows the first metal member 151 to be mounted on the upper surface 11A of the base 11 without being affected by the conductive member provided in the through hole of the base 11. Since the conductive member can protrude slightly upward relative to the upper surface 11A of the base 11 in order to ensure electrical connection, the mounting accuracy of the first metal member 151 is improved by not being affected by the conductive member. Alternatively, even if the degree of protrusion of the conductive member with respect to the upper surface 11A of the base 11 varies due to member tolerance of the conductive member, variation in mounting accuracy of the first metal member 151 can be avoided due to this variation.

The semiconductor laser element 20 is disposed such that the long-side direction in the upper surface 21A and the long-side direction in the package 10 are parallel to each other. Disposing in this manner leads to downsizing of the light-emitting device 1.

One or each of the semiconductor laser elements 20 emits light laterally from the lateral surface 21C that is the light-emitting surface 22. Light traveling in a first direction is emitted from one or each of the semiconductor laser elements 20. In the illustrated light-emitting device 1, the first direction is the same as the X direction. The optical axis of the light emitted from one or each of the semiconductor laser elements 20 is in the same direction as the X direction. The semiconductor laser element 20 may have the light-emitting surface 22 on the upper surface 21A, and may emit light upward from the upper surface 21A.

In the light-emitting device 1, one or each of the reflective members 40 is disposed in the internal space of the package 10. One or each of the reflective members 40 is disposed on the upper surface 11A of the base 11. One or each of the reflective members 40 reflects light emitted from the semiconductor laser element 20. The reflective member 40 is disposed at a position away in the first direction from the semiconductor laser element 20.

Light traveling in the first direction from the semiconductor laser element 20 is reflected by the reflective member 40. The reflective member 40 receives and reflects, on the light-reflective surface 41B, the light emitted laterally from the semiconductor laser element 20 upward.

In order to irradiate the light-reflective surface 41B with the light emitted from the semiconductor laser element 20, the lower surface 21B of the semiconductor laser element 20 is disposed at a position higher than the lower surface 41A of the reflective member 40. Since the first metal member 151 has a thickness of 50 μm or more, it is possible to effectively irradiate the light-reflective surface 41B with divergent light having divergence.

When the distance in the vertical direction from the upper surface 11A of the base 11 to the lower end of the light-reflective surface 41B is in a range from 0 μm to 8 μm, setting the thickness of the first metal member 151 in a range from 70 μm to 130 μm allows the light-reflective surface 41B to be irradiated with a main portion of light and a small light-emitting device to be achieved.

The upper surface 15A of the first metal member 151 is positioned upward relative to the lower end of the light-reflective surface 41B of the reflective member 40. The upper surface 15A of the second metal member 152 is positioned upward relative to the lower end of the light-reflective surface 41B of the reflective member 40. The thickness in the vertical direction of the second metal member 152 is larger than the distance in the vertical direction from the lower surface 41A of the reflective member 40 to the lower end of the light-reflective surface 41B.

When the second metal member 152 is provided for bonding the base 11 and the lid body 14, it is not necessary to make the thickness of the second metal member 152 larger than the distance in the vertical direction from the lower surface 41A of the reflective member 40 to the lower end of the light-reflective surface 41B, and it is less costly to make the thickness thinner. Not providing the second metal member 152 reduces the width in the vertical direction of the package 10, which can also contribute to downsizing of the light-emitting device. On the other hand, the light-emitting device 1 in which the second metal member 152 having the same thickness as that of the first metal member 151 is provided on the base 11 can suppress variation in accuracy due to the tolerance of the upper metal member 15.

The light-emitting device 1 is provided with the one or more wiring lines 60 in order to electrically connect the one or more semiconductor laser elements 20 to the package 10. One or each of the wiring lines 60 electrically connects the one or more semiconductor laser elements 20 and the base 11.

The one or more wiring lines 60 include a wiring line 60 having one end bonded to the upper surface 21A of the semiconductor laser element 20 and the other end bonded to the wiring portion 12A. The one or more wiring lines 60 include a wiring line 60 bonded to the second wiring portion 12A2. A plurality of wiring lines 60 can be bonded to the upper surface 21A of one semiconductor laser element 20.

The light-emitting device 1 can be manufactured by a manufacturing method including preparing the base 11, providing the upper surface of the base 11 with the upper metal member 15, disposing the semiconductor laser element 20 onto the base 11, and bonding the lid body 14 to the base 11.

In providing the upper surface of the base 11 with the upper metal member 15, the upper surface 11A of the base 11 is provided with the first metal member 151 and the second metal member 152 by the same treatment. This can reduce variation in accuracy due to the tolerance generated in manufacturing of the light-emitting device.

For example, collectively forming the first metal member 151 and the second metal member 152 by plating can form the first metal member 151 and the second metal member 152 having a uniform thickness. Even if tolerance of the upper metal member 15 occurs between different light-emitting devices 1, this does not affect the thicknesses of the first metal member 151 and the second metal member 152 in one light-emitting device 1.

The “same treatment” here does not mean requiring simultaneity or positional continuity in a strict sense. As described above, as long as the technique to be used is common and a method suitable for formation with a uniform thickness is adopted, it can be evaluated that the first metal member 151 and the second metal member 152 are collectively formed by the same treatment.

The manufacturing method of the light-emitting device 1 can further include providing the upper surface of the base 11 with the wiring portion 12A and the first bonding pattern 13A1. Providing the first wiring portion 12A1 and the first bonding pattern 13A1 by the same treatment can uniform the thicknesses of the first wiring portion 12A1 and the first bonding pattern 13A1. The “same treatment” here can be understood similarly to the “same treatment” described above.

The manufacturing method of the light-emitting device 1 can further include providing the lower surface of the base 11 with the lower metal member 16. The lower metal member 16 can be formed by a treatment similar to the treatment of providing the upper metal member 15.

In disposing the semiconductor laser element 20 onto the base 11, the semiconductor laser element 20 is disposed on the first metal member 151. In this process, the lower surface 21B of the semiconductor laser element 20 and the upper surface 15A of the first metal member 151 are bonded to each other using an adhesive. As the adhesive, for example, AuSn solder can be used.

In bonding the lid body 14 to the base 11, the base 11 and the lid body 14 are bonded via the second metal member 152. In this process, the second lower surface 14C of the lid body 14 and the upper surface 15A of the second metal member 152 are bonded to each other using an adhesive. As the adhesive, for example, AuSn solder can be used.

The adhesive used in disposing the semiconductor laser element 20 onto the base 11 and the adhesive used in bonding the lid body 14 to the base 11 are the same adhesive. Using the same adhesive can cause a large difference in the thickness of the adhesive cured in each of the both processes not to occur. This can reduce variation in the thickness of the adhesive occurring in the manufacture of the light-emitting device.

### Second Embodiment

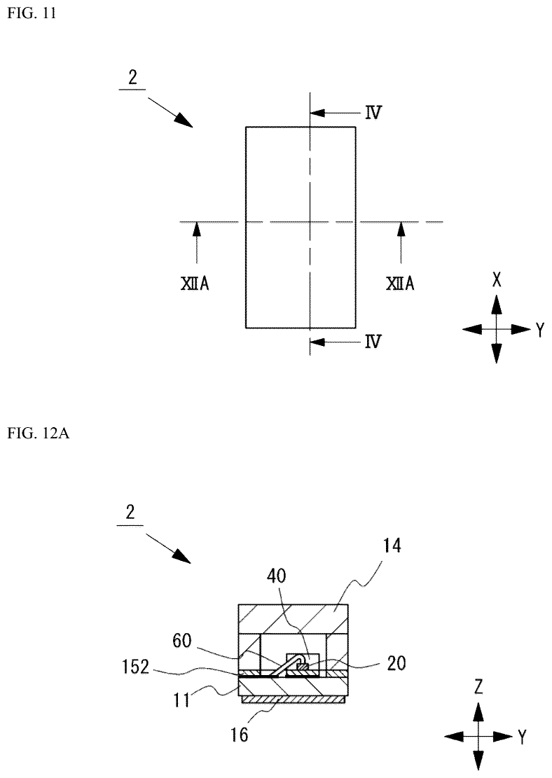

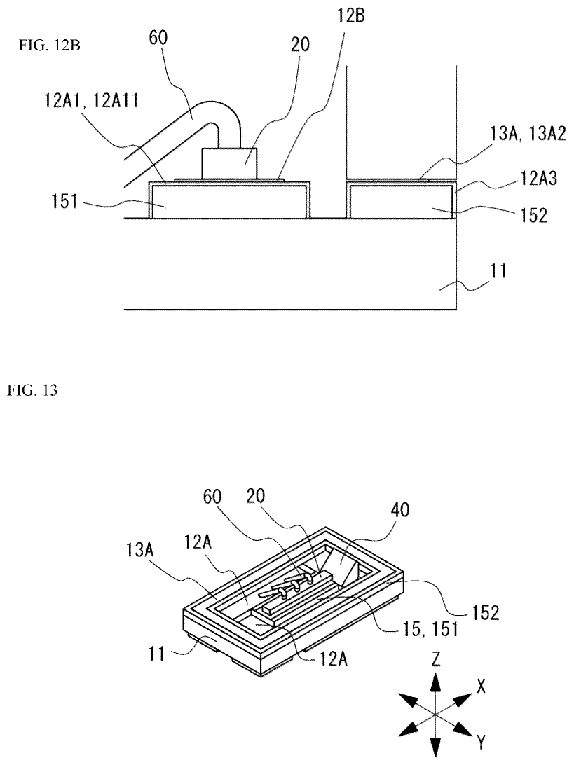

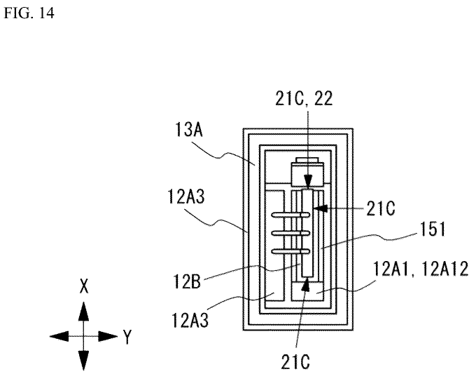

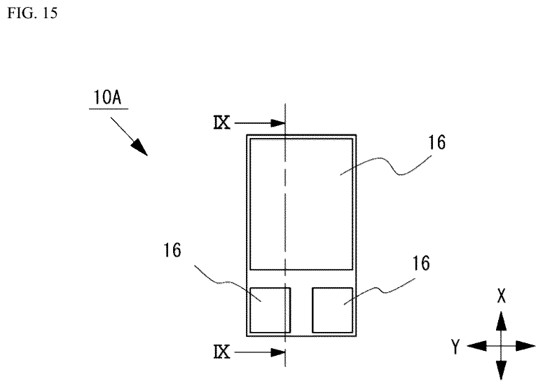

A light-emitting device 2 according to the second embodiment will now be described. FIGS. 3, 4, and 9 to 15 are drawings for illustrating an exemplary embodiment of the light-emitting device 2. FIG. 3 is a side view of the light-emitting device 2. FIG. 4 is a cross-sectional view of the light-emitting device 2 taken along cross section line IV-IV in FIG. 11. FIG. 9 is a cross-sectional view of a package 10A taken along cross section line IX-IX of FIG. 15. FIG. 10 is a perspective view of the light-emitting device 2. FIG. 11 is a top view of the light-emitting device 2. FIG. 12A is a cross-sectional view of the light-emitting device 2 taken along cross section line XIIA-XIIA of FIG. 11. FIG. 12B is a partially enlarged view of FIG. 12A for explaining detailed structures of an upper metal member 15, a wiring portion 12A, and a bonding pattern 13A. FIG. 13 is a perspective view illustrating components disposed inside the package 10A of the light-emitting device 2. FIG. 14 is a top view illustrating the components disposed inside the package 10A of the light-emitting device 2. FIG. 15 is a bottom view of the package 10A.

In the description related to the light-emitting device 1 and each component of the first embodiment described above, all content excluding contents that is deemed to be contradictory from the drawings of FIGS. 3, 4, and 9 to 15 related to the light-emitting device 2 are also applied as the description of the light-emitting device 2. All non-contradictory content will not be repeated here in order to avoid duplication.

The light-emitting device 2 includes the package 10A, the one or more semiconductor laser elements 20, the one or more reflective members 40, and a plurality of wiring lines 60. In the description related to the package 10 of the first embodiment described above, all content excluding contents that is deemed to be contradictory to the package 10A from the drawings of FIGS. 3, 4, and 9 to 15 related to the light-emitting device 2 are also applied as the description of the package 10A. All non-contradictory content will not be repeated here in order to avoid duplication.

### Package 10A

In the package 10 of the light-emitting device 1 according to the first embodiment as described above, the second wiring portion 12A2 and the second metal member 152 are provided on the upper surface 11A of the base 11 while being spaced apart from each other in a top view. In the package 10A according to the second embodiment, a second wiring portion 12A3 and the second metal member 152 are provided in a continuous manner.

The second wiring portion 12A3 is spaced apart from the first metal member 151 in a top view. The second wiring portion 12A3 can be provided on the second metal member 152. The second wiring portion 12A3 has a portion (hereinafter, referred to as a first region of the second wiring portion 12A3) overlapping the second metal member 152 and a portion (hereinafter, referred to as a second region of the second wiring portion 12A3) not overlapping the second metal member 152 in a top view. The second region of the second wiring portion 12A3 is positioned inside the second metal member 152 in a top view. In other words, the second region of the second wiring portion 12A3 is positioned inside the first region of the second wiring portion 12A3 in a top view.

The package 10A provided with the second wiring portion 12A3 can be formed in a smaller size than the package 10 provided with the second wiring portion 12A2 and the bonding pattern 13A. This can achieve a small light-emitting device.

The width in the X direction of the package 10 can be in a range from 2 mm to 4 mm. The width in the Y direction of the package 10 can be in a range from 1.2 mm to 2.9 mm. The width in the Z direction of the package 10 can be in a range from 1 mm to 3 mm.

### Light-Emitting Device 2

In the light-emitting device 2, the one or more wiring lines 60 include a wiring line 60 bonded to the second region of the second wiring portion 12A3. The wiring line 60 is not bonded to the first region of the second wiring portion 12A3.

Although each of the embodiments according to the present invention has been described above, the light-emitting device according to the present invention is not strictly limited to the light-emitting device in each of the embodiments. In other words, the present invention can be achieved without being limited to the outer shape or structure of the light-emitting device disclosed by each of the embodiments. The present invention can be applied without requiring all the components being provided. For example, in a case in which some of the components of the light-emitting device disclosed by the embodiments are not stated in the claims, the degree of freedom in design by those skilled in the art such as substitutions, omissions, shape deformations, and material changes is allowed for those components, and then it is specified that the invention stated in the claims is applied to those components.

The light-emitting device described in the embodiments can be used for a head-mounted display. That is, the head-mounted display is deemed to be one usage in which the present invention is applied. The present invention is not limited to this usage and can be used in various usages such as a projector, lighting, exposure, an in-vehicle headlight, and a backlight of other displays.

### REFERENCE SIGNS LIST

[symbol]

What is claimed is:

1. A light-emitting device comprising:
a base having an upper surface and a lower surface;
a first metal member disposed on the upper surface of the base and having a thickness in a vertical direction in a range from 50 μm to 150 μm;
a second metal member disposed on the upper surface of the base and having a thickness in the vertical direction identical to the thickness of the first metal member, the second metal member being spaced apart from the first metal member in a top view and surrounding the first metal member;
a semiconductor laser element disposed on the first metal member; and
a lid body bonded to the base via the second metal member.

2. The light-emitting device according to claim 1, further comprising
a reflective member disposed on the upper surface of the base and having a light-reflective surface configured to reflect light emitted from the semiconductor laser element, wherein
the semiconductor laser element has a light-emitting surface, and configured to emit light laterally from the light-emitting surface, and
the reflective member is configured to reflect, on the light-reflective surface, the light emitted laterally from the semiconductor laser element upward.

3. The light-emitting device according to claim 1, wherein
a height in the vertical direction of the lid body is in a range from 0.6 mm to 2 mm.

4. The light-emitting device according to claim 1, further comprising
one or more lower metal members provided on the lower surface of the base, wherein
in the top view, the one or more lower metal members includes a first portion overlapping the first metal member and a second portion overlapping the second metal member.

5. The light-emitting device according to claim 4, wherein
in the top view, an area of a region of the second metal member overlapping the one or more lower metal members is larger than an area of a region of the second metal member not overlapping the one or more lower metal members.

6. The light-emitting device according to claim 1, further comprising:
a wiring portion disposed on the upper surface of the base; and
a wiring line bonded to the wiring portion and electrically connecting the semiconductor laser element and the base, wherein
in the top view, the wiring portion is spaced apart from the first metal member.

7. The light-emitting device according to claim 1, wherein
in the top view, the wiring portion is spaced apart from the second metal member.

8. The light-emitting device according to claim 1, wherein
in the top view, the wiring portion includes a first region overlapping the second metal member and a second region positioned inside the second metal member, and
the wiring line is bonded to the second portion of the wiring portion.

9. The light-emitting device according to claim 1, further comprising:
a first wiring portion disposed on the upper surface of the base;
a second wiring portion disposed on the upper surface of the base, the second wiring portion being spaced apart from the first wiring portion in the top view; and
a wiring line bonded to the second wiring portion and electrically connecting the semiconductor laser element and the base, wherein
the first metal member is disposed on the first wiring portion.

10. A manufacturing method of a light-emitting device, the manufacturing method comprising:
preparing a base having an upper surface and a lower surface;
providing a first metal member and a second metal member on the upper surface of the base by the same treatment;
disposing a semiconductor laser element on the first metal member; and
bonding the base and a lid body via the second metal member, wherein
the first metal member and the second metal member have a thickness in a vertical direction identical to each other, and the thickness is in a range from 50 μm to 150 um, and
in a top view, the first metal member is spaced apart from the second metal member and the second metal member surrounds the first metal member.
